(19) United States
(12) Patent Application Publication
(10) Pub. No.: US 2010/0027223 A1
(43) Pub. Date: Feb. 4, 2010

(54) SEMICONDUCTOR INTEGRATED CIRCUIT HAVING HEAT RELEASE PATTERN

(75) Inventors: Joon Ho Na, Daejeon-si (KR); Dae-Keun Han, Daejeon-si (KR); Dae-Seong Kim, Daejeon-si (KR)

Correspondence Address: Jae Y. Park, Kile, Goekjian, Reed & McManus, PLLC, 1200 New Hampshire Ave. NW, Suite 570, Washington, DC, 20036, US

(73) Assignee: SILICON WORKS CO., LTD., Daejeon-si (KR)

(21) Appl. No.: 12/520,088

(22) PCT Filed: Nov. 26, 2007
(86) PCT No.: PCT/KR2007/005979

§ 371 Date: Aug. 12, 2009

(30) Foreign Application Priority Data
Dec. 21, 2006 (KR) 10-2006-01311969

(51) Int. Cl. H05K 7/20; H01L 23/34

(52) U.S. Cl. 361/719; 257/713; 257/E23.08

(57) ABSTRACT

Provided are a semiconductor integrated circuit having a heat release pattern in a chip so as to release heat generated inside the chip and a system board having a heat release unit used to release heat generated inside the semiconductor integrated circuit. The semiconductor integrated circuit includes: one or more output pads directly connected to an output terminal having a heat release pattern; a power supply pad supplying power; and one or more dummy pads connected to a metal line for supplying power or an internal output terminal of an internal function block, wherein the heat release pattern includes a plurality of unit contacts at the output terminal or a plurality of strip contacts having an area of about or larger than the sum of two or more of the unit contacts.

### BACKGROUND OF THE INVENTION

1. Field of the Invention

The present invention relates to a semiconductor integrated circuit, and more particularly, to a semiconductor integrated circuit having a heat release pattern which can easily release heat generated inside the semiconductor integrated circuit.

2. Description of the Related Art

In the description, a semiconductor integrated circuit is used together with a chip in which the semiconductor integrated circuit is implemented.

The semiconductor integrated circuit includes a large number of transistors. Due to power consumed by each of the transistors, a temperature of the semiconductor chip in which the integrated circuit is implemented increases. Particularly, heat generated from an output circuit consuming the highest power increases the temperature of the chip at the highest rate. When the temperature of the semiconductor chip increases, mobility of carriers forming currents of the transistors also increases, so that electrical characteristics of the transistors are changed. In order to design the integrated circuit, a predetermined design margin is considered so that the integrated circuit has heat-resistance to temperature change. However, when the increase in the temperature overtakes the design margin, errors in the integrated circuit may occur.

In order to prevent the increases in the temperature of the semiconductor chip, a heat sink is mounted to an upper portion of the chip to release heat generated inside the chip. However, the heat sink can be applied only when the semiconductor chip is packaged to be used, and additional costs to use the heat sink are needed. In order to satisfy the demand of users requiring various functions, a system becomes complex, and this causes the increase in an area of the system. In addition, a method of mounting the semiconductor chips that are components of the system to a system board while the semiconductor chips are assembled also causes the increases in the area of the system.

Therefore, in order to decrease the area of the system, a method of mounting the semiconductor chips to the system board without assembling the semiconductor chips is proposed. In this method, since the semiconductor chips are not assembled, the heat sink cannot be used, so that a new heat release method is needed.

### SUMMARY OF THE INVENTION

The present invention provides a semiconductor integrated circuit having a heat release pattern inside a chip so as to release heat generated inside the chip.

The present invention also provide a system board having a heat release unit for releasing heat from a heat release pattern disposed inside the chip so as to release the heat generated inside the chip.

According to an aspect of the present invention, there is provided a semiconductor integrated circuit including: one or more output pads directly connected to an output terminal having a heat release pattern; a power supply pad supplying power; and one or more dummy pads connected to a metal line for supplying power or an internal output terminal of an internal function block, wherein the heat release pattern includes a plurality of unit contacts at the output terminal or a plurality of strip contacts having an area of about or larger than the sum of two or more of the unit contacts.

According to another embodiment of the present invention, there is provided system board including: a semiconductor integrated circuit including one or more output pads connected to an output terminal having one or more unit contacts or an output terminal having one or more strip contacts having an area of about or larger than the sum of two or more of the unit contacts, one or more power supply pads supplying power to the semiconductor integrated circuit, and one or more dummy pads connected to a metal line for supplying power to the semiconductor integrated circuit or an output terminal of an internal function block disposed in the semiconductor integrated circuit; and one or more heat release units connected to the output pads, the power supply pads, and the dummy pads.

### BRIEF DESCRIPTION OF THE DRAWINGS

The above and other features and advantages of the present invention will become more apparent by describing in detail exemplary embodiments thereof with reference to the attached drawings in which:

FIG. 1 is a view illustrating a layout of an output terminal implemented in a semiconductor integrated circuit according to an embodiment of the present invention;

FIG. 2 is a view illustrating a layout of an output terminal implemented in a semiconductor integrated circuit according to another embodiment of the present invention;

FIG. 3 is a view illustrating relationships between output pads connected to output terminal metal illustrated in FIGS. 1 and 2 and heat release units disposed at a system board;

FIG. 4 is a view illustrating an arrangement of normal pads and dummy pads used for a semiconductor integrated circuit and heat release units disposed at a system board according to an embodiment of the present invention; and

FIG. 5 is a view illustrating an arrangement of dummy pads used for a semiconductor integrated circuit and heat release units disposed at a system board according to another embodiment of the present invention.

### DETAILED DESCRIPTION OF THE INVENTION

Hereinafter, exemplary embodiments of the present invention will be described in detail with reference to the attached drawings.

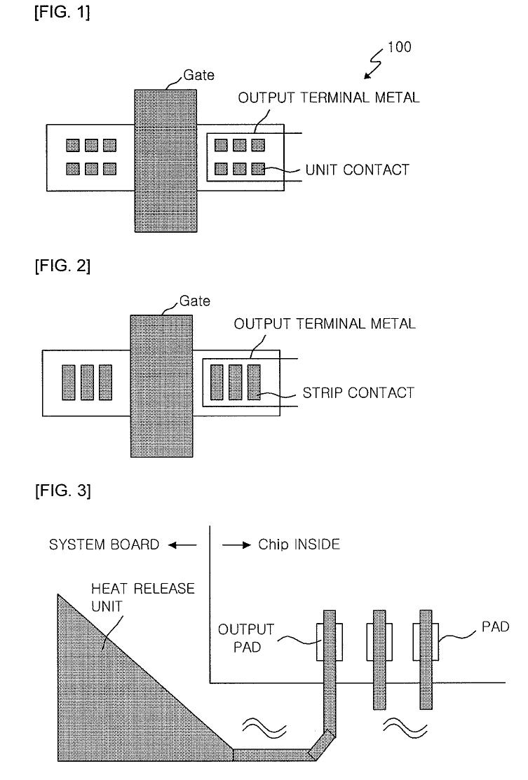

FIG. 1 is a view illustrating a layout of an output terminal implemented in a semiconductor integrated circuit according to an embodiment of the present invention.

Referring to FIG. 1, the output terminal implemented in the semiconductor integrated circuit according to the embodiment of the present invention includes a first heat release pattern, specifically, two or more unit contacts. Since a temperature of the output terminal of a chip consuming high power increases, the core idea of the present invention is to increase a diffusion area for externally outputting a signal and provide contacts to the diffusion region as many as possible. The signal of the output terminal is directly connected to an output pad through output terminal metal deposed on the unit contacts. Therefore, when heat can be released from the output pad, heat generated inside the semiconductor integrated circuit can be effectively released.

FIG. 2 is a view illustrating a layout of an output terminal implemented in a semiconductor integrated circuit according to another embodiment of the present invention.

Referring to FIG. 2, the output terminal implemented in the semiconductor integrated circuit according to the embodiment of the present invention includes a second heat release pattern, specifically, two or more strip contacts. The strip contact has an area of about or larger than the sum of two or more of the unit contacts illustrated in FIG. 1. The number of the strip contacts is smaller than the number of the unit contacts illustrated in FIG. 1. However, the area of the strip contact is larger than that of the unit contact, so that the total area for releasing heat can be increased.

Referring to the layouts of the output terminals implemented in the semiconductor integrated circuits according to the embodiments of the present invention illustrated in FIGS. 1 and 2, by increasing the number of the contacts used by the heat release pattern, that is, the output terminal, increasing an area occupied by the contacts, or using the two methods, paths for releasing heat generated from the output terminals can be increased.

FIG. 3 is a view illustrating relationships between the output pads connected to the output terminal metal illustrated in FIGS. 1 and 2 and the heat release unit disposed at a system board.

Referring to FIG. 3, the output pad disposed inside the semiconductor integrated circuit is connected to the heat release unit disposed at the system board. The heat release unit generally includes copper. However, any conductive material that can be electrically connected to the output pad can be used for the heat release unit.

The heat generated from the heat release pattern of the output terminal of the semiconductor integrated circuit is transferred to the heat release unit through the output terminal metal and the output pad, so that more heat can be released in a short time as the area of the heat release unit increases. The heat release unit is disposed at the system board, but is insulated from other conductors that are disposed at the system board to be paths of electrical signals. In addition, the system board is generally grounded, so that noises and power input to the heat release unit are blocked. Therefore, the heat release unit only releases the heat generated inside the semiconductor integrated circuit connected to the heat release unit and does not affect other electrical characteristics.

Referring to FIG. 3, for the convenience of description, only a single output pad is provided to the chip. However, the above description can be applied to output terminals to which much heat is released from the chip or pads to which a source voltage is supplied. When there is an area in which dummy pads can be used at a boundary of the chip, in addition to the pads to which the source voltage is applied, the source voltage is extended from the inside to the dummy pads, and the heat release unit is connected to the dummy pad. And, in addition to the output terminals connected to the output pad, output terminals in an internal function block that release much heat can be connected to the dummy pads.

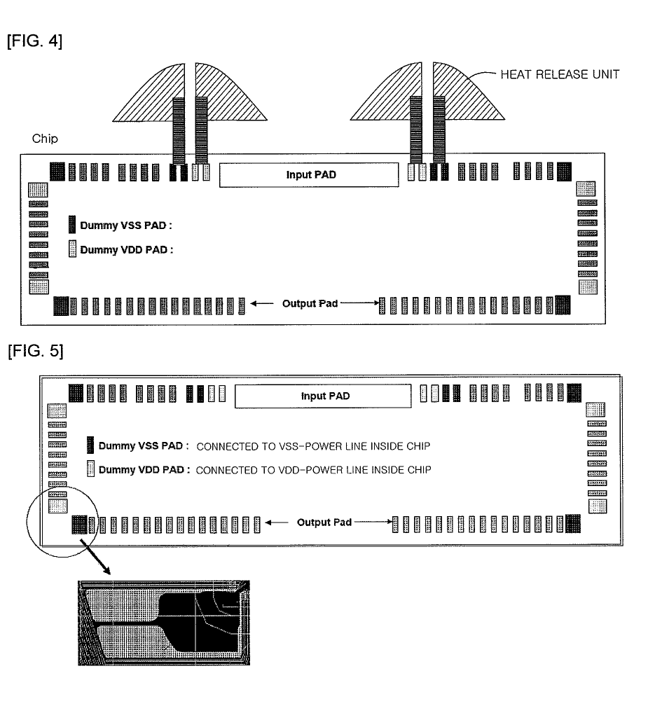

FIG. 4 is a view illustrating an arrangement of normal pads and dummy pads used for the semiconductor integrated circuit and heat release units disposed at a system board according to an embodiment of the present invention.

Referring to FIG. 4, a heat release unit (inside the circle) connected to the dummy pads of the semiconductor integrated circuit is mounted to the system board, and as a size of the heat release unit increases, more heat can be released. In the drawings, VSS dummy pads and normal output pads are connected to the heat release unit. However, the description can be applied to VDD dummy pads.

FIG. 5 is a view illustrating an arrangement of dummy pads used for a semiconductor integrated circuit and heat release units disposed at a system board according to another embodiment of the present invention.

Referring to FIG. 5, two dummy pads (for VSS and VDD) disposed at a corner (inside the circle) of the semiconductor integrated circuit are connected to two heat release units disposed at the system board, respectively. Therefore, heat transferred to the two heat release units through the two heat release patterns (not shown), the output terminal metal (not shown), and the dummy pads is released to an upper portion of the system board. As the size of the heat release unit increases, an ability to release the heat can be improved.

The dummy pads have the same or similar shapes as to those of the normal pads disposed inside the chip and are used as paths for releasing the heat to the outside of the chip.

As described above, the heat release unit disposed at the semiconductor integrated circuit or at the system board connected to the output pads and the heat release patterns of the semiconductor integrated circuit can be used to effectively release heat generated inside the semiconductor integrated circuit.

While the present invention has been particularly shown and described with reference to exemplary embodiments thereof, it will be understood by those skilled in the art that various changes in form and details may be made therein without departing from the spirit and scope of the present invention as defined by the appended claims.

What is claimed is:

1. A semiconductor integrated circuit comprising:
one or more output pads directly connected to an output terminal having a heat release pattern;
a power supply pad supplying power; and
one or more dummy pads connected to a metal line for supplying power or an internal output terminal of an internal function block,
wherein the heat release pattern includes a plurality of unit contacts at the output terminal or a plurality of strip contacts having an area of about or larger than the sum of two or more of the unit contacts.

2. The semiconductor integrated circuit of claim 1, wherein the dummy pad is directly connected to the metal line for supplying power and the internal output terminal of the internal function block inside the semiconductor integrated circuit.

3. A system board comprising:
a semiconductor integrated circuit including one or more output pads connected to an output terminal having one or more unit contacts or an output terminal having one or more strip contacts having an area of about or larger than the sum of two or more of the unit contacts, one or more power supply pads supplying power to the semiconductor integrated circuit, and one or more dummy pads connected to a metal line for supplying power to the semiconductor integrated circuit or an output terminal of an internal function block disposed in the semiconductor integrated circuit; and
one or more heat release units connected to the output pads, the power supply pads, and the dummy pads.

4. The system board of claim 3, wherein the heat release units connected to the power supply pads and the dummy pads having the same electrical characteristics are connected to each other on the system board.

5. The system board of claim 3, wherein a material used to electrically connect the heat release units, input/output pads of the semiconductor integrated circuit, the power supply pad, and the dummy pads to the system board has the same component as a material of the metal line used in the semiconductor integrated circuit.

6. The system of claim 5, wherein the component of the heat release unit is copper.
